(19) United States
(12) Patent Application Publication
(10) Pub. No.: US 2025/0285847 A1
(43) Pub. Date: Sep. 11, 2025

(54) RADIO FREQUENCY SYSTEM PROTECTION BASED ON TEMPERATURE INFERENCE

(71) Applicant: Lam Research Corporation, Fremont, CA (US)

(72) Inventors: David French, Fort Myers, FL (US); Yaswanth Rangineni, Portland, OR (US)

(73) Assignee: Lam Research Corporation, Fremont, CA (US)

(21) Appl. No.: 18/861,528

(22) PCT Filed: Apr. 29, 2023
(86) PCT No.: PCT/US2023/020505

§ 371 Date: Oct. 29, 2024

Related U.S. Application Data
(60) Provisional application No. 63/365,992, filed on Jun. 7, 2022.

(51) Int. Cl. H01J 37/32; G01K 1/02; G01K 3/00; G01K 7/00; G01R 25/00

(52) U.S. Cl. CPC H01J 37/32935; G01K 1/026; G01K 3/005; G01K 7/00; G01R 25/00; H01J 37/32091; H01J 37/321; H01J 2237/24585

(57) ABSTRACT

Described is a method for thermally protecting an electronic circuit. In at least one implementation, electronic circuit comprises at least a first component and a second component. In at least one implementation, method comprises measuring a first input voltage and a first input current of the first component. In at least one implementation, method further comprises computing a second input voltage and a second input current of the second component. In at least one implementation, method further comprises computing a first temperature of the first component and a second temperature of the second component, wherein the first temperature is a function of the first input current and the second temperature is a function of the second input current.

### CLAIM FOR PRIORITY

This application claims the benefit of priority to U.S. Provisional Patent Application No. 63/365,992, filed on Jun. 7, 2022 and titled “Radio Frequency System Protection Based on Temperature Inference,” which is incorporated by reference in its entirety for all purposes.

### BACKGROUND

Process tools are used to perform treatments such as deposition and etching of film on semiconductor wafer substrates. These process tools may utilize plasmas for etching, substrate cleaning and deposition. The plasma may be created and sustained by capacitive or inductive coupling to fields that are generated, controlled and distributed by a power delivery network external to the chamber. The power delivery network may deliver power from a radio frequency power generator to a coupling interface. A coupling interface may be an inductance coil, an antenna or a capacitive electrode, coupling RF energy stored in magnetic or electric fields to the plasma. Due to fluctuations in electron density and currents within the coupled plasma, impedance loading of the power delivery network may fluctuate. Impedance mismatch between the plasma and the power delivery network, including impedance matching networks, may occur randomly or systematically due to process drift, causing coupling losses due to power reflection at the coupling interface. The losses may result in lower power efficiencies and changes in process performance. The power delivery network may comprise multiple components in series and parallel combinations. Power delivery network components may include passive LC filters, transmission lines, and the like. Reflected power due to large impedance mismatch at the interface may cause excess current flow through one or more components in the power delivery network, causing excess heating of the components. Some components may be damaged by the excess heating. Current solutions for protection of sensitive power delivery components include installation of multiple temperature sensors along the power delivery network component chain to monitor temperatures of individual or grouped heat-sensitive components. Remedies to the excess current draw may be to flag the situation and automatically or manually limit power to the plasma. Other remedies may include placing an upper limit on the maximum power usable for the plasma tool. These solutions involving multiple temperature sensors may be expensive and difficult to implement. Additionally, a cutback of plasma power may unnecessarily limit the peak power deliverable to the plasma.

### BRIEF DESCRIPTION OF THE DRAWINGS

Material described herein is illustrated by way of example and not by way of limitation in the accompanying figures. For simplicity and clarity of illustration, elements illustrated in the figures are not necessarily drawn to scale and exact locations. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a cross-sectional view of a plasma processing tool, according to at least one implementation.

FIG. 2 illustrates a portion of a power delivery network, showing cascaded components and conditions at nodes between components, including transformation sequences of measured and calculated voltages and currents at each node, according to at least one implementation.

FIG. 3 illustrates a method for obtaining thermal constants of electrical components in a power delivery network, according to at least one implementation.

FIG. 4 illustrates a method for determining temperatures of multiple cascaded components in a power delivery network, according to at least one implementation.

FIG. 5 illustrates a plot showing calculated and measured values of temperature vs. time for an exemplary component in a power delivery network, according to at least one implementation.

FIG. 6 illustrates a processor system with machine-readable storage medium, according to at least one implementation.

### DETAILED DESCRIPTION

Disclosed herein is an apparatus and method to protect plasma power delivery network components from overheating and potential failure, according to at least one implementation. Such component overheating may occur when a mismatch occurs between instantaneous plasma impedance relative to tuned impedance matches between components of plasma power delivery network. A large impedance mismatch may cause a large amount of power to reflect from a plasma coupling interface, such as a coil, through an impedance matching network back through power delivery network. Reflected power may result in intercomponent impedance mismatches and may cause excess current to flow through one or more of components. Some components may comprise single or multiple temperature-sensitive circuit elements, which may overheat because of excessive current flow. Temperatures reached may exceed thermal limits for circuit elements given by manufacturer. Thus, circuit element may be damaged or destroyed by a large heat input, potentially causing power delivery network to fail.

Disclosed method provides, among other benefits, an improvement upon existing power-delivery component protection methods in plasma processing systems, according to at least one implementation. Disclosed method employs a single point of measurement of RF voltage and current along power delivery network, according to at least one implementation. Benefits provided include, among others, a reduction or elimination of temperature sensors that would be employed to conventionally monitor temperatures of plasma circuitry components, according to at least one implementation. Such temperature sensors are often difficult to install and increase operational complexity of plasma processing tools when employed. In addition, incorporation of temperature sensors may increase purchase and maintenance costs of plasma processing tool.

In at least one implementation, voltage and current may be physically measured at a single convenient node between any two components along cascaded components of power delivery network. In at least one implementation, measured RF voltage and current may comprise RF voltage across an input port of a first component on downstream side of node, and RF current flowing into input port of first component. In at least one implementation, measured RF voltage and current may be equal to voltage across output port of a second, or upstream component and current flowing out of output port of upstream component.

In at least one implementation, RF current and voltage, once measured, may be transformed to currents and voltages at other nodes along power delivery network component chain by application of transfer functions and/or transfer matrices. In at least one implementation, by monitoring voltage and current at a single node within power delivery network, currents and voltages at multiple nodes within power delivery network may be simultaneously calculated. In at least one implementation, currents flowing into each component and/or node voltages across input terminals of an individual component may be known within acceptable error tolerances. In at least one implementation, once determined, calculated currents and/or voltages may be converted to input power to individual components. In at least one implementation, a portion of input power may be dissipated as heat through circuit element resistances and dielectric losses.

In at least one implementation, circuit elements within an individual component may have predetermined thermal constants. In at least one implementation, after determination of currents and voltages at multiple nodes within power delivery network, calculated input powers may be applied to a thermal calculation tailored to each circuit element within a component. Instantaneous estimated temperatures of each circuit element may be determined. In at least one implementation, single voltage and current sensor may be read periodically by a microprocessor to update status of measured node. In at least one implementation, cascade of afore-mentioned computations may be repeated, updating temperature status of one or more of components on a periodic basis.

Thus, when a significant impedance mismatch condition occurs, disclosed method may provide calculated temperatures for each circuit element within each component within power delivery network without employing temperature sensors, in accordance with at least one implementation. In at least one implementation, any significant temperature rise of components or individual circuit elements within a component may be detected. In at least one implementation, an alarm is set to users of plasma chamber tool to mitigate excess temperature. In at least one implementation, a correction routine is triggered to cause a reduction of excess temperature. In at least one implementation, RF energy may be delivered in bursts to plasma. Such bursts may have a duty cycle, where on time and off time may be adjusted within a duty cycle period. In at least one implementation, by reducing on time of duty cycle, average power delivered to plasma may be reduced without decreasing voltage or current amplitudes of power waveform.

In at least one implementation, calculated temperatures may indicate a thermal overlimit (or overtemperature) condition for certain circuit elements. To remedy overtemperature condition, in at least one implementation, peak RF power and RMS (root mean square) power from RF source may be left constant while average power delivered to plasma is reduced. In at least one implementation, voltages and currents at an individual node along power delivery network follow duty cycle adjustment of RF current flow. In at least one implementation, global reduction of current flow time phase of duty cycle, may allow a decrease of temperature of all circuit elements, while leaving peak levels of current and voltage substantially constant, thus protecting most heat-vulnerable components. In at least one implementation, duty cycle may be re-adjusted after impedance mismatch condition is corrected or diminished.

In some instances, well-known methods and devices are shown in block diagram form, rather than in detail, to avoid obscuring present disclosure. Reference throughout this specification to “an implementation” or “one implementation” or “some implementations” means that a particular feature, structure, function, or characteristic described in connection with implementation is included in at least one implementation of disclosure. Thus, appearances of phrase “in an implementation” or “in one implementation” or “some implementations” in various places throughout this specification are not necessarily referring to same implementation of disclosure. Furthermore, particular features, structures, functions, or characteristics may be combined in any suitable manner in one or more implementations. For example, a first implementation may be combined with a second implementation anywhere particular features, structures, functions, or characteristics associated with two implementations are not mutually exclusive.

Here, “coupled” and “connected,” along with their derivatives, may be used to describe functional or structural relationships between components. These terms are not intended as synonyms for each other. Rather, in particular implementations, “connected” may be used to indicate that two or more elements are in direct physical, optical, or electrical contact with each other. Here, “coupled” may be used to indicate that two or more elements are in either direct or indirect (with other intervening elements between them) physical, electrical or in magnetic contact with each other, and/or that two or more elements co-operate or interact with each other (e.g., as in a cause an effect relationship). Here, “coupled” may also generally refer to direct attachment of one electronic component to another. An electric or magnetic field may couple one component to another, where field is controlled by one component to influence other in some manner.

Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by “at least one of” or “one or more of” can mean any combination of listed terms.

Here, “adjacent” may generally refer to a position of a thing being next to (e.g., immediately next to or close to with one or more things between them) or adjoining another thing (e.g., abutting it).

Unless otherwise specified in explicit context of their use, “substantially equal,” “about equal” and “approximately equal” may generally mean that there is no more than incidental variation between two things so described. In at least one implementation, such variation is typically no more than +/−10% of a referred value.

Here, “process tool” may generally refer to a semiconductor process tool such as a plasma process tool, which may include a chamber equipped with an antenna coil that is coupled to a radio frequency (RF) signal source. In at least one implementation, antenna coil is utilized to generate electromagnetic fields, which in turn generates an inductive electric field through a transformer action that sustains plasma.

Here, “upstream” and “downstream” may generally refer to predominant direction of power flow, mostly in terms of current flow. In at least one implementation, an upstream component is on source, or generator, side of a node, and a downstream component is on load side of a node, where power flows from source to load.

Here, “node” may generally refer to a point between output port of upstream component and input port of adjacent downstream component. In at least one implementation, components themselves of power delivery network are treated as two-port networks, comprising an input port and an output port. In at least one implementation, each port has two terminals. In at least one implementation, two-port networks may be or include passive LC filters or individual inductors, resistors and capacitors. In addition to passive LC devices, in at least one implementation, two-port networks may include transmission lines, switches, RF chokes, etc.

Here, “terminal” may generally refer to end of a conductor or electrical component, such as a wire, which may be a point of connection for other conductors or electrical components. In context of a coil, in at least one implementation, terminal is end of a winding. Referring to coil segments, in at least one implementation, coil segment may comprise a terminal at beginning and end of a coil segment conductor.

Here, “inductor” may generally refer to a passive electrical device that stores magnetic energy from an electrical current flowing through it. In at least one implementation, an inductor may comprise a conductor (e.g., a metal wire) that may couple an electrically generated magnetic field into another conductor that is nearby, inducing a voltage and current in second conductor. In at least one implementation, magnetic field may be generated by currents flowing within first conductor according to Faraday's law of induction. Conductors have property of inductance, which is a function of magnitude of current flowing within conductor and shape or geometry of conductor. While any conductor may be an inductor, some shapes produce a stronger inductance than others. A straight wire may have a small inductance that is dependent on its diameter and length. A straight wire may be wound into a coil to multiply inductance by number of windings per unit length, for example, due to mutual additive coupling of magnetic fields between each winding, reinforcing overall magnetic field. Magnetic fields from each winding couple produce a multiplication of magnetic field produced by straight wire, according to Ampere's law. In at least one implementation, coil may be a planar coil, or a helical coil, such as a solenoid or tapered helix.

Here, “capacitor” may generally refer to a passive electrical device that stores electrical charge and electrical energy in form of an electric field. In at least one implementation, a capacitor generally has at least two conductive plates in proximity to one another, separated by a dielectric material. In at least one implementation, dielectric material may be air (or other gas) or vacuum. In at least one implementation, dielectric may generally be a solid or liquid material, such as a polymer, a ceramic, or a semi-liquid electrolyte. In at least one implementation, opposite electrical charges may accumulate on adjacent plates, forming an electric field extending from plate to plate through dielectric. In at least one implementation, electric field can store electrical energy.

Here, “radio frequency” abbreviated as RF, may generally refer to a portion of electromagnetic spectrum having frequencies ranging between 10 kilohertz (kHz) to several hundred gigahertz (GHz).

Here, “plasma” may generally refer to a gaseous formation comprising charged particles, such as positively or negatively charged atomic or molecular ions and electrons. Plasmas are considered fourth state of matter.

Here, “inductively coupled plasma” (abbreviated as ICP) may generally refer to a plasma that is generated by time-varying magnetic fields emanating from a primary inductor or plasma antenna, generally in form of a coil, conducting an RF current. In at least one implementation, a small concentration of ionized atoms or molecules and free electrons within a gas may be generated in a discharge. In at least one implementation, slightly ionized gas may be regarded as a secondary inductor coupled to plasma antenna, which may be considered primary inductor of a transformer where plasma may be considered secondary inductor of transformer to which primary is coupled. In at least one implementation, gas may pass through an electromagnetic field produced by adjacent ICP antenna, where charges are accelerated by time-varying electric fields associated with time-varying magnetic fields (according to Faraday's law of induction and Faraday-Maxwell equation). In at least one implementation, accelerated electrons may collide with neutral atoms or molecules to produce more ions and secondary electrons, building up plasma density of charged particles. In at least one implementation, magnitude of particle acceleration and hence collision velocity is proportional to strength of electric fields which in turn are proportional to magnetic field strength. In at least one implementation, ultimately, magnetic field strength is proportional to magnitude of current flowing within ICP antenna.

Here, “ICP antenna” may generally refer to an inductor through which an RF current may pass and may radiate RF power to a limited extent as near-field static and propagating electromagnetic fields. In at least one implementation, RF current flows through ICP antenna, generating an electromagnetic field that couples to a partially ionized gas or to a fully developed plasma. In at least one implementation, former may be caused to develop into a plasma by action of electromagnetic field.

Here, “capacitively coupled plasma” (CCP) may generally refer to a plasma capacitively coupled to an electric field between two or more electrodes within a plasma chamber.

Here, “transmission line” may generally refer to a cable comprising at least two conductors in parallel and closely spaced. In at least one implementation, transmission line generally carries equal and opposite currents and voltages for each conductor. Magnetic fields of opposed currents cancel, greatly reducing or eliminating radiation of electromagnetic radiation from conductors. In at least one implementation, a transmission line may carry RF current and voltages from a source to a load, such as an antenna without radiating RF energy. Transmission lines have a characteristic impedance.

Here, “dielectric material” may generally refer to a non-electrically conductive material, such as a polymer, a ceramic, glass, wood, etc.

Here, “radio frequency” (RF) may generally refer to electromagnetic radiation that oscillates at frequencies in a spectrum that is substantially inclusive of frequencies between 10 kilohertz (kHz) and 1 terahertz (THz, or 10¹⁵ Hz). In at least one implementation, upper limit of radio frequency spectrum may extend only to several hundred gigahertz (GHz). Radio frequency as a term is commonly abbreviated to “RF”.

Here, “RF signal source” may generally refer to an electronic device that can generate electrical signals at radio frequency. In at least one implementation, RF signal source is capable of outputting significant RF current (e.g., 1 Ampere rms or greater) at significant voltages. In at least one implementation, RF signal sources for ICP antennas generally are capable of outputting up to hundreds of amperes at up to several hundred volts, generating significant electrical power.

Here, “circuit element” may generally refer to an electronic device, active or passive, that may be part of an electronic circuit.

Here, “passive element” may generally refer to an electric element that has an output response that is not controllable by an electronic signal where output response is related to an input signal, such as a voltage and/or current. In at least one implementation, a passive element is a resistor, where voltage drop across resistor is not controllable by a separate electronic signal, and is simply a function of current flowing through it. Other examples of passive elements are capacitors and inductors. In at least one implementation, a passive element may be modelled as a two-port component. In at least one implementation, an active element is an electronic device such as a transistor comprising at least a third port at which a control signal is applied to control output of device.

Here, “component” may generally refer to a circuit element or a combination of circuit elements, passive and/or active, that is or are part of a network.

Here, “network” may generally refer to a plurality of circuit elements connected together to form an electronic circuit. In at least one implementation, network generally has two or more ports.

Here, “port” may generally refer to a network terminal where signals may be introduced or exit network. In at least one implementation, a network generally has at least two ports, at least one port being an input port, and at least a second port being an output port.

Here, “input” may generally refer to a network port where signals enter network. Input signals may be input voltages and input currents.

Here, “output” may generally refer to a network port where signals exit network. In at least one implementation, output signals may be output voltages and output currents.

Here, “impedance” may generally refer to resistance of a circuit element to alternating current, generally at audio and RF frequencies. In at least one implementation, impedance may be a general term for electrical resistance. In at least one implementation, reactance is impedance of a capacitor or an inductor. In at least one implementation, reactance is different from resistance in that it is not dissipative (no power lost as heat). Impedance is defined as ratio of voltage to current. Complex impedance is a combination of a resistance and a reactance, where reactance is an imaginary value, and resistance is a real value. Complex impedance may be expressed in polar coordinates as a magnitude and phase angle, where phase angle is phase between voltage and current.

Here, “input impedance” and “output impedance” may generally refer to impedances of an input port and of an output port, respectively. They are ratio of input voltage to input current, and output voltage to output current, respectively.

Here, “impedance matching network” may generally refer to an electronic network that matches an output impedance to an input impedance.

Here, “LC filter” may generally refer to an electronic network comprising a combination of passive inductors (L) and capacitors (C) to pass certain frequencies that are input to filter circuit. In at least one implementation, LC filters are high pass filters, low pass filters, bandpass filters and notch filters. In at least one implementation, LC filters may also be impedance matching networks.

Here, “power delivery network” may generally refer to an electronic circuit comprising a plurality of electrical components that may be coupled together. In at least one implementation, components are coupled together in series (cascaded). In at least one implementation, power delivery network may be designed to convey RF power from a source to a load.

Here, “cascaded” may generally refer to combining of networks in series, so that output of a first network is input of a second network coupled to first network.

Here, “process tool” may generally refer to a piece of equipment employed in semiconductor fabrication, also referred to as a “semiconductor process tool” for semiconductor processing. In at least one implementation, process tool may generally comprise a vacuum chamber in which processes such as substrate plasma etching, or plasma-enhanced material deposition are carried out. In at least one implementation, Other non-plasma related processes may also be performed in a process tool.

Here, “chuck” may generally refer to a stage or platform on which a substrate (e.g., a wafer) may be attached.

Here, “substrate” may generally refer to a wafer comprising a semiconductor (e.g., silicon) or an insulator (e.g., aluminum nitride, silicon carbide, silicon nitride, aluminum oxide, float glass, borosilicate glass, etc.). In at least one implementation, a wafer may be a slice of monocrystalline semiconductor or insulator. In at least one implementation, a wafer may also comprise a polycrystalline or an amorphous (glassy) material. In at least one implementation, wafer may have a diameter generally ranging between 100 mm to 500 mm, and a thickness generally ranging between 100 microns and 1 mm.

Here, “process chamber” may generally refer to a vacuum chamber of a process tool into which a substrate may be introduced for processing. In at least one implementation, a process chamber may include a chuck for holding substrate. In at least one implementation, a process chamber is a plasma etch chamber.

Here, “magnetic field” may generally refer to lines of magnetic flux direction and intensity emanating from a magnetized material or current-carrying material.

Here, “plasma-enhanced process” may generally refer to a semiconductor process, for example, where a plasma is employed to aid process in some way. In at least one implementation, a plasma enhanced process is enhanced over a similar or same process without a plasma. An example is reactive ion etching and plasma-enhanced chemical vapor deposition or plasma enhance atomic layer deposition.

Here, “reactive species” may generally refer to electrons, ions or neutral radicals formed in a plasma.

Here, “ion” may generally refer to a charged atom or molecule. In at least one implementation, an ion may be a gaseous atom or molecule that loses or gains an electron in a plasma.

Here, “machine-readable storage medium” may generally refer to a memory that stores binary code or data that is readable by a processor. In at least one implementation, a machine-readable storage medium may be a non-volatile solid state storage medium, a volatile memory, a magnetic hard drive, an optical disc, etc.

Here, “machine-readable instructions” may generally refer to binary code stored on a machine-readable storage medium. When executed, binary instructions may cause a processor to perform certain functions.

Here, “transfer matrix” may generally refer to sets of interdependent linear equations in matrix form for computing a first voltage and a first current at a first node from a second voltage and a second current at a second node. In at least one implementation, second voltage and second current may be measured or computed. In at least one implementation, matrix may generally be a 2×2 matrix; larger matrices such as 3×3 matrices may be applied. In at least one implementation, transfer matrices may be applied to transform a first voltage and a first current at a first node within an electronic circuit to second voltage and a second current at a second node. In at least one implementation, impedances may be similarly transformed.

Here, “transfer function” may generally refer to an equation that computes an input voltage or current of a circuit or circuit component to an output voltage or current of circuit or circuit component. Terms of equation may include combinations of circuit component values. Transfer functions may equally be applied to compute output voltages and/or currents from input voltages and/or currents.

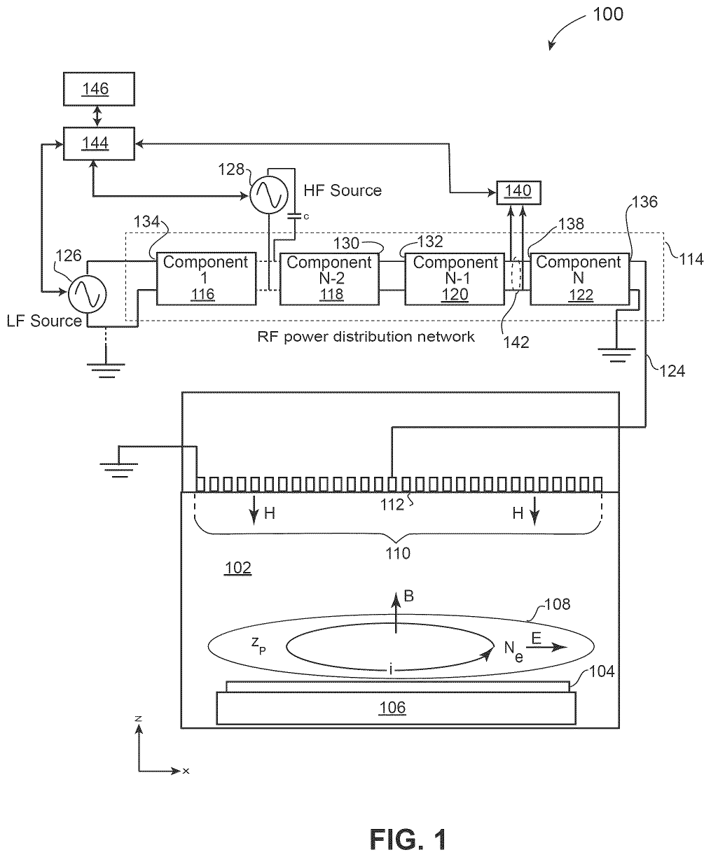

FIG. 1 illustrates a cross-sectional view of plasma processing tool 100, in accordance with at least one implementation. In at least one implementation, plasma processing tool 100 comprises a plasma chamber 102 for plasma-enhanced processing of wafer 104, chuck 106, plasma 108, antenna 110, wall 112, and power delivery network 114.

In at least one implementation, chuck 106 may support wafer 104 and electrically stabilize wafer 104 in presence of plasma 108. In at least one implementation, chuck 106 may be grounded or biased. In at least one implementation, bias may be a DC voltage, or a periodic voltage waveform applied to chuck 106. In at least one implementation, plasma 108 may be an inductively coupled plasma (ICP), generated and sustained within plasma chamber 102 by radio frequency (RF) electromagnetic fields radiated by ICP antenna 110. In at least one implementation, radiated electromagnetic field is indicated by down-pointing arrows representing RF magnetic field labelled H, and horizontal arrow representing RF electric field labelled “E”. In at least one implementation, RF E fields may ionize gaseous atoms and molecules introduced into plasma chamber 102, creating gaseous ions and free electrons. In at least one implementation, free electrons may form plasma currents that follow trajectories perpendicular to RF H fields, as shown. In at least one implementation, plasma currents in turn may produce induced magnetic fields B that couple back to ICP antenna 110. In at least one implementation, plasma 108 is electromagnetically coupled to ICP antenna 110. In at least one implementation, plasma 108 may be a capacitively coupled plasma (CCP), where an electrode (not shown) within plasma chamber 102 is coupled to plasma 108 by an RF electric field extending between electrode and chuck 106, for example.

In at least one implementation, ICP antenna 110 can be isolated from plasma chamber 102 by wall 112 to protect it and any associated electronics from plasma 108. ICP antenna 110 may be fed by RF power distribution network 114. In at least one implementation, power delivery network 114 may comprise a plurality of N components, where N≥1, here represented by components 116, 118, 120, and 122. In at least one implementation, components 116-122 may represent a portion of RF power delivery network 114. In at least one implementation, N may be four or greater. Component 116 is labelled component 1 and may be viewed as first component in component chain of RF power delivery network 114. In at least one implementation, portion of RF power delivery network 114 may be viewed as source end. In at least one implementation, next component in component chain, component 118, is labelled component N−2. If N>4, then N−2>2, and one or more components may be included between component 116 and component 118. In at least one implementation, remaining components 120 and 122 are respectively labelled component N−1 and component N, where component N is final component in component chain. In at least one implementation, while components 116-122 (and further components not shown) are shown to be coupled in series, some components may also be coupled in parallel.

In at least one implementation, components 116, 118, 120, and 122 are represented as cascaded two-port networks, each component having an input port and an output port. In at least one implementation, in arrangement of RF power delivery network 114, component 116 is upstream of components 118-122 from point of view of power flow within RF power delivery network 114. Repeating definitions given above, here “upstream” refers to “towards source”, and “downstream” refers to “towards load”. In at least one implementation, power flows from source to load. Here, source may be RF source 126 and/or RF source 128, load being ICP antenna 110, in accordance with at least one implementation.

In at least one implementation, output port of an upstream component may be coupled to input port of an adjacent downstream component. Output port 130 of component 118 may be coupled to input port 132 of component 120, where component 120 is downstream of component 118, in accordance with at least one implementation. Couplings between output ports and input ports may be referred to as nodes. In at least one implementation, a node may be bounded by input port of upstream component and output port of adjacent downstream component. Nodes may be characterized by a node voltage and node current. In at least one implementation, node voltage may be output voltage Vₒᵤₜ of upstream component, measured across two terminals. In at least one implementation, node current may be output current Iₒᵤₜ of upstream component that flows as Iᵢₙ into input port of downstream component.

In at least one implementation, if input impedance Zᵢₙ of each input port, defined as ratio of Vᵢₙ/Iᵢₙ, is matched to output impedance Zₒᵤₜ, defined as Vₒᵤₜ/Iₒᵤₜ of each output port, Vₒᵤₜ=Vᵢₙ and Iₒᵤₜ=Iᵢₙ. In at least one implementation, for an impedance mismatch condition, Vₒᵤₜ and Vᵢₙ across a node may differ, while Iₒᵤₜ and Iᵢₙ may also differ. In at least one implementation, lack of continuity of voltage and current across a mismatched node may result from reflected voltage and current waves due to impedance mismatch.

In at least one implementation, individual components 116-122 may comprise passive circuits comprising circuit elements such as inductors (L), capacitors (C), resistors (R) and switches. In at least one implementation, at least some of components 116-122 may comprise LCR (inductor, capacitor, and resistor) circuit elements may be combined in filter circuits, where low pass, high pass, bandpass or notch filter may be constructed. In at least one implementation, one or more components 116-122 may comprise impedance-matching networks comprising LC circuits arranged as “L” network topologies, “T” network topologies, “Pi” network topologies or combinations thereof.

In at least one implementation, components 116-122 may also include passive circuit elements such as, but not limited to, switches, transmission lines, transformers, directional couplers, power splitters, power combiners, individual inductors (e.g., RF chokes), and capacitors. In at least one implementation, these components may be employed for decoupling and blocking of LF (low-frequency) and HF (high-frequency) currents, for example. Transmission lines (e.g., transmission line 124) may be a coaxial transmission line or a two-conductor open wire line. In at least one implementation, transmission lines may couple component 122 at load end of RF power delivery network 114 to ICP antenna 110. In at least one implementation, component 122 may itself be a transmission line, with transmission line 124 being an extension of component 122 coupling to ICP antenna 110.

In at least one implementation, ICP antenna 110 may be coupled to RF signal sources 126 and 128 at input port 134 of component 116 at upstream, or generator, end of component chain. In at least one implementation, RF signal source 126 is a low frequency (LF) RF signal source or generator, whereas RF signal source 128 is a high frequency (HF) signal generator. In at least one implementation, RF signal source 126 may generate frequencies below 1 MHz, whereas an RF signal source 128 may generate frequencies above 1 MHz. RF signal sources 126 and 128 may output pure sine wave voltages or other voltage waveforms such as square waves, sawtooth waves, triangle waves and other suitable waveforms. In at least one implementation, RF signal sources 126 and 128 may be capable of large power generation, for example, outputting up to 10 kilowatts of power (several hundred volts and 10s of Amperes).

In at least one implementation, while RF signal source 126 is shown to be differentially coupled to power delivery network 114, it may be optionally coupled by a single-ended connection, where one terminal is grounded. In at least one implementation, this configuration is indicated by dashed line connecting ground symbol to lower side of RF source 126. In at least one implementation, while RF signal source 128 is also shown to be differentially coupled to RF power delivery network 114, it may also be coupled in a single ended coupling to RF power delivery network 114. In at least one implementation, two RF signal sources are shown to be coupled to RF power delivery network 114. In some implementations, a single RF signal source may be employed. In at least one implementation, multiple RF (e.g., more than two) signal sources may be employed.

In at least one implementation, ICP antenna 110 is in form of a coil. As noted above, ICP antenna 110 may be isolated from plasma chamber 102 by wall 112. In at least one implementation, wall 112 comprises a dielectric material to permit electric and magnetic fields from ICP antenna 110 to couple with plasma 108 within plasma chamber 102. In at least one implementation, while ICP antenna 110 is shown as a flat, or “pancake” coil, IPC antenna 110 may have other suitable shapes, such as a serpentine coil or a helical solenoid coil. Individual windings of antenna coil are shown in cross-sectional illustration. ICP antenna 110 is shown as a planar spiral coil (e.g., a “pancake coil”) in illustrated implementation, comprising multiple windings, shown in cross section. In at least one implementation, for tubular chamber geometries, ICP antenna 110 may also have a helical (e.g., solenoidal) geometry. In at least one implementation, a solenoid may generally have a cylindrical form factor, where a conductor may be in form of a helical coil.

In at least one implementation, as already noted, plasma 108 is coupled to ICP antenna 110 through RF electromagnetic fields emanating from ICP antenna 110. In at least one implementation, electromagnetic fields sustain plasma 108. In at least one implementation, electric fields E may be large enough to ionize low pressure gases introduced into plasma chamber 102, which generally is pumped down to a high vacuum. In at least one implementation, free electrons formed by electric fields may form circular plasma currents under influence of magnetic field H extending from ICP antenna 110. In at least one implementation, density of free electrons ne within plasma 108 is at least in part a function of supplied RF power, which may manifest as electric and magnetic field strengths E and H, respectively. In at least one implementation, RF frequency may also influence free electron density ne. In at least one implementation, higher frequencies may increase rate of formation of free electrons by increasing number of collisions between ions and gaseous atoms or molecules, and between electrons and gaseous atoms.

In at least one implementation, free electron density ne within plasma 108 may be a parameter determining plasma impedance. In at least one implementation, plasma impedance may be represented as an electric impedance Zₚ comprising a series combination of a resistance and an inductance. In at least one implementation, plasma impedance Zₚ may be proportional to free electron density. In at least one implementation, inductance of plasma may be associated with induced magnetic fields B generated by circular plasma currents i (also proportional to ne) that coupled back to ICP antenna 110. In at least one implementation, interaction between ICP antenna 110 and plasma 108 may be similar to interaction between a transformer primary winding and secondary winding.

In at least one implementation, coupling between plasma 108 and ICP antenna 110 may influence input impedance Zₐₙₜ of ICP antenna 110. In at least one implementation, an impedance matching network may be necessary to match Zₐₙₜ to components within RF power delivery network 114 that are upstream of ICP antenna 110 to RF signal sources 126 and 128. In at least one implementation, RF signal sources 126 and 128 may both have an output impedance Z_{gen} of 50 ohms, for example. In at least one implementation, system impedance of RF power delivery network may be designed for 50 ohms, meaning Zᵢₙ and Zₒᵤₜ for each component are also substantially 50 ohms for a matched condition. Zₐₙₜ of ICP antenna 110 may differ significantly from 50 ohms.

In at least one implementation, a matching network may transform Zₐₙₜ to 50 ohms. In at least one implementation, component 122 (e.g., component N) at load end of RF power delivery network 114 may comprise an LC impedance matching L or Pi network, for example, providing appropriate match. In at least one implementation, component 122 may be a transmission line, engineered to transform Zₐₙₜ to system impedance. In at least one implementation, a transmission line may have a characteristic impedance Z₀ between Zₐₙₜ and 50 ohms. In at least one implementation, transmission line length (including transmission line 124) may be adjusted to match Zₐₙₜ to system impedance (e.g., 50 ohms). In at least one implementation, transmission line length may be cut to a quarter of wavelength of HF frequency (e.g., a Q-section) if Z₀ is approximately equal to geometric mean of Zₐₙₜ and system impedance.

In at least one implementation, fluctuations of Zₐₙₜ may be due in part to fluctuations of plasma impedance Zₚ during a process because of, for example, momentary changes of gas flow rates or pressure within plasma chamber 102. In at least one implementation, fluctuations of Zₚ may cause detuning of matching network of component 122, causing input impedance of component 122 (e.g., Z_{Nin}) to change. In at least one implementation, change in Z_{Nin} by detuning of component 122 may cause a mismatch to output impedance Z_{N-1out} of component 120 (component N−1). In at least one implementation, mismatch to output impedance may initiate a propagation of impedance mismatches at each node in component chain of RF power delivery network 114 up to RF signal sources 126 and 128.

In at least one implementation, a matching network (e.g., component 122) may include variable capacitors and/or inductors as circuit elements to enable tuning of matching network to follow fluctuations in Zₐₙₜ resulting from fluctuations of Zₚ. In at least one implementation, matching network (e.g., component 122) may be tuned to accommodate a small range of plasma impedances. In at least one implementation, tuning may be in part performed by including variable capacitors or inductors also in upstream components to match output and input impedances Zᵢₙ and Zₒᵤₜ between adjacent components. In at least one implementation, values of a LC filter circuit elements within one component may be adjusted to produce desired matching impedances to match those of adjacent upstream and downstream components. This approach may be cumbersome as controls for each component to drive variable capacitors or inductors would be necessary.

Assuming output impedance of component 122 may have been adjusted for a specified Zₐₙₜ, input impedance Z_{Nin} of component 122 seen by output impedance Z_{N-1out} of component 120 may change in such a way that component 120 may draw a greater current. In addition, power to plasma 108 may be reduced by current and voltage reflections occurring at output port 136 of component 122. Amount of power reflected back to input port 138 of component 122 may be expressed by reflection coefficients ρ for reflected current and voltage from node 142 between component 122 and transmission line 124. Reflected RF current and voltage waves may set up standing waves along transmission line 124 and partially within component 122. For large standing wave ratios (SWR), current standing waves may comprise current peaks that are much larger than ratings of circuit elements within component 122. Some circuit elements may not safely carry such high currents. Overheating may occur if circuit elements are subjected to currents exceeding a manufacturers' ratings of circuit elements. Overheating of individual circuit elements may lead to failure of component as a whole. In some instances, coupling of power source (e.g., RF signal sources 126 and/or 128) to ICP antenna 110 may become gradually detuned with time. This gradual detuning may cause a more gradual impedance mismatch between RF signal source and plasma 108. Impedance mismatch may increase gradually with time.

While above description has been focused on inductively coupled plasma systems, in at least one implementation, a capacitively coupled plasma (CCP) system may be employed for plasma process tool 100. In at least one implementation, in a CCP system, plasma chamber 102 includes a pair of electrodes separated by a distance. In at least one implementation, one of pair of electrodes may be a CCP electrode. In at least one implementation, CCP electrode may be a metallic object within plasma chamber 102, where CCP electrode is in direct contact with a plasma (e.g., plasma 108). In at least one implementation, a second of pair of electrodes may be, for example, chuck 106. In at least one implementation, plasma may be generated between CCP electrode and chuck 106. In at least one implementation, wafer 104 rests on chuck 106, as shown. In at least one implementation, chuck 106 may be grounded or biased in a CCP system. In at least one implementation, bias may be DC or RF. In at least one implementation, RF source 126 may provide a low-frequency RF bias to chuck 106 if it is coupled to a low pass filter. RF signal source 128 may provide primary high frequency RF coupling to plasma 108. In at least one implementation, electrode is a gas distribution manifold (e.g., a heated showerhead) located above wafer 104 supported on chuck 106. In at least one implementation, frequency differentials between RF signal sources 126 and 128 may be substantial, for example having a spread of 10:1 or higher.

In at least one implementation, during operation, plasma 108 is formed above wafer 104 and chuck 106. RF magnetic fields penetrating plasma chamber 102 may produce plasma currents that may oscillate at same frequency of RF currents flowing in power delivery network 114. In at least one implementation, RF currents may have peak magnitudes of tens to several hundred amperes. In at least one implementation, sensor 140, to measure voltages and currents, may be coupled to any suitable node within RF power delivery network 114. In at least one implementation, sensor 140 may be an RF current and/or voltage measuring sensor (e.g., a V, I sensor), a vector network sensor, an impedance sensor, etc. In at least one implementation, sensor 140 may be a V, I sensor, to measure both RF voltages and currents, coupled to RF power delivery network 114 at node 142 between components 120 and 122, as shown. In at least one implementation, sensor 140 may be interfaced to circuitry permitting coupling to processor 144. In at least one implementation, sensor 140 may provide a digitized output stream to processor 144, which may be read and analyzed by software code stored in memory 146 coupled to processor 144. In at least one implementation, memory 146 may be a machine-readable storage medium, such as a non-volatile solid-state memory, a hard disc magnetic drive, an optical drive, and other suitable storage formats. In at least one implementation, memory 146 may store a computer program comprising machine-executable instructions. In at least one implementation, processor 144 may be part of a control circuitry for plasma process tool 100, either local or remotely coupled though a network.

In at least one implementation, processor 144 may execute software code comprising routines containing instructions to compute voltages and currents at each node within RF power delivery network 114, based solely on voltages and/or currents read at single node 142. In at least one implementation, software routines stored in memory 146 may comprise instructions according to method implementations described in this disclosure. In at least one implementation, computed currents and/or voltages may be transformed to power dissipated within individual components (e.g., components 116-122) as heat. In at least one implementation, derived power figures may be inserted into thermal equations contained within software code stored in memory 146, determining calculated temperatures of components or individual circuit elements within individual components. In at least one implementation, sequence of calculations may be made for selected components or their circuit elements if, for example, they are identified as temperature sensitive. In at least one implementation, processor 144 is also coupled to RF signal sources 126 and 128, as shown. In at least one implementation, processor 144 may communicate with RF signal sources 126 and 128 to control output power and/or duty cycle, for example, in response to a detected overtemperature condition. A more complete description of control instructions is given below.

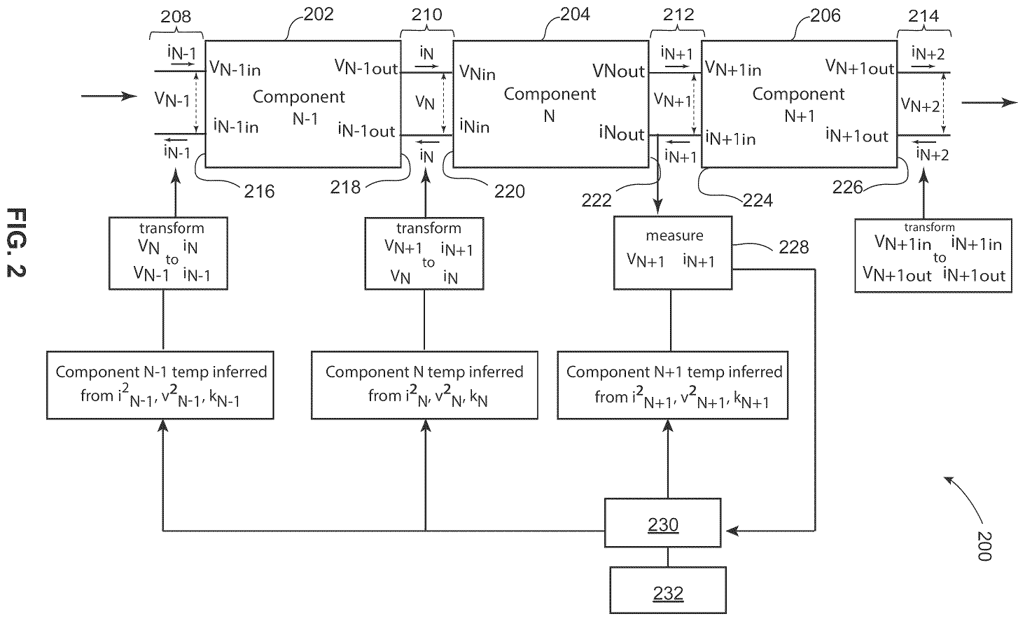

FIG. 2 illustrates a graphical representation of a method for obtaining component temperatures within RF power delivery network 200 comprising cascaded components, in accordance with at least one implementation. Voltage and current conditions at each node are indicated. In FIG. 2, a portion of RF power delivery network 200 comprising components 202, 204, and 206 is shown, in accordance with at least one implementation. Components 202, 204 and 206 are labelled component N−1, component N and component N+1, respectively. In at least one implementation, components 202-206 are part of a larger RF power delivery network 200, comprising preceding and succeeding portions. In at least one implementation, preceding portion may comprise a plurality of upstream components (e.g., components labelled 1, 2 . . . . N−2). In at least one implementation, succeeding portion may comprise a plurality of downstream components (e.g., components labelled N+2, N+3 etc.).

In at least one implementation, adjacent upstream and downstream components are coupled by a node. In at least one implementation, node 210 couples component 202 to component 204, whereas node 212 couples component 204 to component 206. In at least one implementation, nodes 208 and 214 are terminal nodes. In at least one implementation, while terminal nodes 208 and 214 appear to be open-ended in figure, it will be understood node 208 is also coupled to an adjacent upstream component N−2, not shown, and that node 214 is coupled to an adjacent downstream component N+2, also not shown in figure.

In at least one implementation, individual components within RF power delivery network 200 may be represented as two-port networks, comprising an input port and an output port. In at least one implementation, component 202 comprises input port 216 and output port 218. Individual nodes 208-214 are each bounded by output port of an upstream component and input port of adjacent downstream component. In at least one implementation, node 210 is bounded by output port 218 of component 202 and input port 220 of component 204, node 212 is bounded by output port 222 of component 204 and input port 224 of component 206. In at least one implementation, ports comprise two terminals. In at least one implementation, input ports 216, 220, 224 may be characterized by input voltages Vᵢₙ and input currents Iᵢₙ. In at least one implementation, for individual input ports 216, 220, and 224, input voltages are indicted by V_{N-1in}, V_{Nin} and V_{N+1in}, respectively. In at least one implementation, designations follow component positions in component chain, for example V_{N-1in} corresponds to component N−1, etc. In at least one implementation, output ports 218, 222, and 226 may be similarly characterized by output voltage and current indications. In at least one implementation, nodes 208, 210, 212, and 214 may also be characterized by node voltages and currents. In at least one implementation, node 210 may be characterized by node voltage V_{N} and current i_{N}, where subscript N refers to downstream component (e.g., component 204).

In at least one implementation, likewise, node 212 between components N and N+1 (204 and 206, respectively) may be characterized by V_{N+1} and i_{N+1}, etc. In at least one implementation, within an individual node, upstream output voltages and currents may be substantially equal to downstream input voltages and currents if output impedance Zₒᵤₜ of upstream component is matched to input impedance Zᵢₙ of downstream component (e.g., Zₒᵤₜ=V/i=Zᵢₙ). In at least one implementation, if an impedance mismatch occurs downstream in component chain of RF power delivery network 200, Zᵢₙ of downstream component may change significantly with respect to Zₒᵤₜ of upstream component. In at least one implementation, if plasma impedance Zₚ fluctuates and is no longer matched by a matching network, an impedance mismatch condition occurs at load end of RF power delivery network 200. In at least one implementation, impedance mismatch may propagate up component chain causing an impedance mismatch at each node within component chain. In at least one implementation, V_{N-1out} and i_{N-1out} at output port 218 of component 202 are substantially equal to V_{Nin} and I_{Nin} at input port 220 of component 204 when Z_{N=1out}=Z_{Nin}. In at least one implementation, when Z_{N=1out}≠Z_{Nin}, equivalency between output and input voltage and currents may no longer be true. In at least one implementation, reflections of voltage and current waves may occur at node boundaries.

In at least one implementation, because of an impedance mismatch condition, output ports 218, and 222 may see a mismatched Zᵢₙ looking into adjacent input ports 220 and 224. In at least one implementation, this condition is propagated up component chain, where Zᵢₙ of each component will also appear to change in view of adjacent component upstream of it, terminating at any RF signal source (e.g., RF signal source 126 and/or RF signal source 128 shown in FIG. 1). In at least one implementation, power may also be reflected by each mismatched node, potentially resulting in increased current draw in some or all components in RF power delivery network 200. In at least one implementation, current drawn by some components may increase beyond rated limits, potentially causing overheating of individual circuit elements within individual components. In at least one implementation, component 204 may comprise an LC filter circuit comprising capacitors and inductors. In at least one implementation, while normal current levels may cause either or both circuit elements to dissipate heat, excess current flow may cause overheating of either or both circuit elements. In at least one implementation, circuit elements may have a maximum temperature rating. If maximum temperature rating is exceeded, circuit element may be damaged or destroyed.

In at least one implementation, a method for obtaining temperatures of components 202, 204 and 206 for protection of temperature-sensitive components or circuit elements within some or all components is graphically represented by FIG. 2. In at least one implementation, a sensor 228 to measure RF current and voltage (e.g., such as sensor 140 in FIG. 1) may be coupled to any node within RF power delivery network 200. In at least one implementation, sensor 228 is coupled to node 212 between components 204 and 206 (e.g., component N and component N+1). In at least one implementation, sensor 228 may continuously measure node voltage and node current V_{N+1} and i_{N+1}. In at least one implementation, once measured, V_{N+1} and i_{N+1} values may be continuously read by processor 230. In at least one implementation, processor 230 may compute V and i values at other nodes (e.g., V_{N-1}, i_{N-1}. V_{N}, i_{N}, V_{N+2}, i_{N+2} at nodes 208, 210 and 214, respectively), by use of mathematical transformations employing transfer functions and/or transfer matrices. In at least one implementation, transfer matrices, for example, comprise sets of interdependent linear equations in matrix form for computing a first voltage and a first current at a first node from a second voltage and a second current at a second node. In at least one implementation, second voltage and second current may be measured or computed.

In at least one implementation, second voltage and second current may be linearly combined by matrix coefficients. In at least one implementation, matrix coefficients transform second voltage and second current to first voltage and first current. In at least one implementation, matrix coefficients may be transfer functions that transforming second voltage and second current to first voltage, and for transforming second voltage and second current to first current. In at least one implementation, transfer matrix may be encoded into machine-readable instructions that may be stored in memory 232 coupled to processor 230. In at least one implementation, transfer matrices may be employed to transform measured voltages and currents at node 212 to voltage and current values at node 210. In at least one implementation, an exemplary transfer matrix for a two-port electric network may have form given by equation [1]:

$$[ \begin{matrix}{V}_{1} \\ {I}_{1}\end{matrix} ] = [ \begin{matrix}A & B \\ C & D\end{matrix} ] [ \begin{matrix}{V}_{2} \\ - {I}_{2}\end{matrix} ] \qquad [ 1 ]$$

where V₁ may be voltage across a first (e.g., input) port, and I₁ may be current flowing into first port. V₂ may be voltage across second (e.g., output) port, and I₂ may be current flowing out of second port. In at least one implementation, coefficients A, B, C and D may be determined empirically for individual components. In at least one implementation, A=[V₁/V₂]_{I2=0}; B=[−V₁/I₂]_{V2=0}; C=[I₁/V₂]_{V1=0}; D=[V₂/V₁]_{I1=0}. In at least one implementation, in circuits comprising resistive and/or reactive elements, values of coefficients A, B, C, and D may be based on reactance and susceptance values related to individual circuit elements combined in specific circuit topologies within components 202, 204 and 206.

In at least one implementation, transfer matrices may be cascaded to compute voltages and currents at nodes upstream and downstream of node 212 along component chain of RF power delivery network 200.

In at least one implementation, node calculations based on cascaded transfer matrices may have form given in equation [2]:

$$[ \begin{matrix}{V}_{N - 1} \\ {I}_{N - 1}\end{matrix} ] = [ \begin{matrix}{A}_{N - 1} & {B}_{N - 1} \\ {C}_{N - 1} & {D}_{N - 1}\end{matrix} ] [ \begin{matrix}{V}_{N} \\ {I}_{N}\end{matrix} ] = [ \begin{matrix}{A}_{N} & {B}_{N} \\ {C}_{N} & {D}_{N}\end{matrix} ] [ \begin{matrix}{V}_{N + 1} \\ {I}_{N + 1}\end{matrix} ] \qquad [ 2 ]$$

In at least one implementation, equation [2] may be encoded into software stored in memory 232 and solved numerically. In at least one implementation, coefficients A, B, C, and D may be predetermined for some or all components or for selected temperature-sensitive circuit elements. In at least one implementation, processor 230 may read sensor 228 at predetermined time intervals. In at least one implementation, sensor 228, coupled to node 212, measures values of V_{N+1} and i_{N+1}. In at least one implementation, processor 230 may compute values of voltage and current V_{N} and I_{N} from node 210 by transformation of voltages and currents V_{N+1} and I_{N+1} measured at node 208. In at least one implementation, once values of input voltage and current may be determined at other nodes 208, 210, and 214.

In at least one implementation, once i_{in N+1} is measured and i_{inN} and i_{inN+1} are computed based on I_{in N+1}, power dissipation within individual components 202, 204, and 206 may be determined from computed values of i_{inN-1} and i_{inN} and, for example. In at least one implementation, knowledge of circuit topology and dielectric and series resistance values losses of individual circuit elements such as capacitors and inductors may be invoked. In at least one implementation, based on calculated node currents, heat generated by Joule heating (I²R) losses for each component, for example, may be calculated. Here, knowledge of series resistance and dielectric loss parameters for inductors and capacitors, for example, may be used.

In at least one implementation, a change in temperature may occur within each component because of excess Joule heating due to I²R losses, where I may include excess input current to component. R may represent a series resistance or dielectric loss. In at least one implementation, a temperature rise within individual components may be determined by numeric calculations performed by a processor 230. In at least one implementation, processor 230 may execute software instructions stored in memory 232 to compute quasi-instantaneous temperatures, for example, into numerical heat transfer differential equations. In at least one implementation, such numerical heat transfer differential equations may have form of equation [3]:

$$T ( {t}_{n} ) = {k}_{1} ( {T}_{0} - T ( {t}_{n - 1} ) ) Δ t + {{k}_{2} ( I , V )}^{2} ( {t}_{n} ) Δ t \qquad [ 3 ]$$

where T(tₙ), Tₒ, k₁ and k₂ Δt are respectively component temperature at time tₙ, tₙ is nth time increment, To is a reference temperature, k₁ and k₂ are constants related to energy gain and loss of system. At is time increment. In at least one implementation, thermal constants k₁ and k₂ may be determined empirically for individual components (e.g., components 202, 204 and 206). An exemplary procedure for determining thermal constants k₁ and k₂ is described below. In at least one implementation, T(t_{N}) profiles may be determined in real time by repeated numerical solution of equation 3 for some or all components within RF power delivery network 200. In at least one implementation, software may comprise instructions to further determine if a rated temperature of a component or circuit element within a component has been exceeded at any point in process. In at least one implementation, last term of equation [3] is Joule heating term, a numerical integral of electrical power to compute Joule in terms of I²R or V²/R.

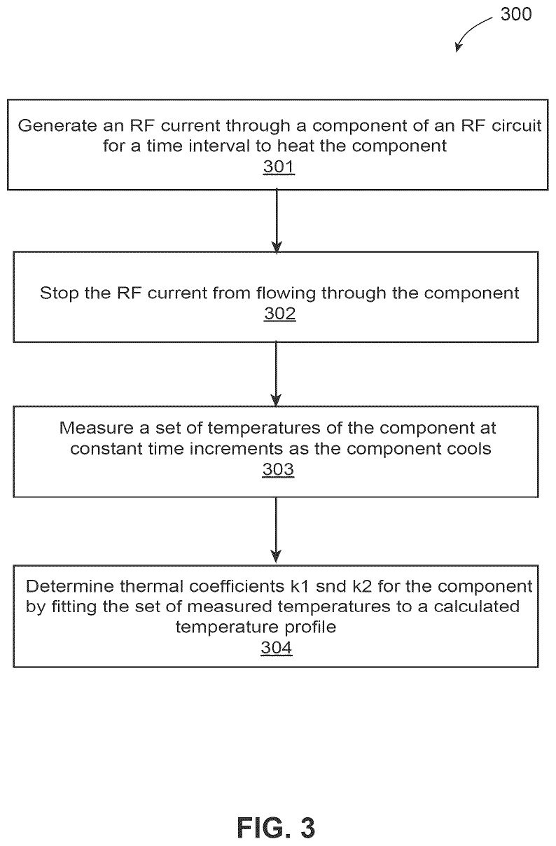

FIG. 3 illustrates method 300 for obtaining thermal constants of electrical components in a power delivery network (e.g., power delivery network 114 or 200), in accordance with at least one implementation. In at least one implementation, various blocks or operations may be performed by hardware, software, or a combination of both. Method 300 provides thermal protection for temperature sensitive components within power delivery network, in accordance with at least one implementation. In at least one implementation, method 300 may be carried out by a digital processor executing machine-executable instructions in a computer program stored in memory coupled to processor, in accordance with some implementations. In at least one implementation, thermal characterization of a component under test to be employed in an RF power delivery network, such as RF power delivery network 114 shown in FIG. 1 or RF power delivery network 200 shown in FIG. 2, may be determined empirically. In at least one implementation, component under test is subjugated to realistic power delivery conditions that may be envisioned in actual use of power delivery network. In at least one implementation, method illustrates operations that may be employed to obtain thermal characteristics, such as thermal constants k₁ and k₂ of component under test. In at least one implementation, component under test may be a real component employed in an RF power delivery network.

In at least one implementation, at operation 301, an RF current may be generated by an RF signal source, such as RF signal source 126 or 128, where RF signal source is coupled to component under test. In at least one implementation, RF current may flow through component under test. In at least one implementation, component under test may comprise a combination of passive circuit elements or may comprise a single circuit element. In at least one implementation, circuit elements may include passive elements such as, but not limited to, capacitors, inductors, transformers, resistors, directional couplers, power splitters and combiners, switches, and transmission lines. In at least one implementation, RF current may be chosen to have an RMS value that heats component by Joule heating, quantified as I²R heating. In at least one implementation, quantity R may be equivalent series resistance of component and may be responsible for dissipative losses in component. In at least one implementation, current I may be RMS RF current value, which is substantially equivalent numerically to a DC current passing through same component that causes same amount of I²R heating in component. In at least one implementation, a 1 Ampere peak amplitude of a sinusoidal RF current has an RMS value of approximately I=0.7 Ampere, which is equivalent to I=0.7 Ampere DC in terms of I²R heating. In at least one implementation, RF current may be delivered in bursts governed by a duty cycle, where RF current is switched on and off on a periodic basis, in contrast to a continuous delivery of RF current that may be controlled by adjusting its peak amplitude. In at least one implementation, for RF current controlled by a duty cycle, relevant parameters may be length of duty cycle period and percentages of on and off times within a duty cycle period.

In at least one implementation, duty cycle period may be sum of on-time and off-time phases of duty cycle. In at least one implementation, by governing RF current as controlled bursts or pulses, average RF current delivered to component under test may be adjusted by adjusting on-time and off-time durations of duty cycle. In at least one implementation, temperature rise within component under test may be proportional to average RF current when pulsed, and not peak RF current. In at least one implementation, peak RF current may remain constant, which may enable peak power delivered to a plasma to be as high as required to maintain desired plasma characteristics such as electron density ne. In at least one implementation, on-time and off-time phases of duty cycle may be measured on time scale of seconds. Both parameters may be optimized.

In at least one implementation, flowing RF current in bursts may provide maximum peak power delivery to a plasma while limiting amount of time components are subject to Joule heating. In at least one implementation, peak power may be maintained to generate desired electron densities within plasma, for example. In at least one implementation, component may support peak values of current that significantly surpass manufacturer ratings for short periods of time. In at least one implementation, adjusting on-time of duty cycle may permit temperature transient developed during current burst to relax, effectively permitting component under test to cool between current bursts. In at least one implementation, during operation 301, component is allowed to heat up to an elevated temperature by flowing current for a set period of time.

In at least one implementation, at operations 302 and 303, current is halted and component under test is permitted to cool. In at least one implementation, during cooling phase, falling temperature of component under test may be recorded by a temperature sensor. In at least one implementation, a thermocouple, infrared camera, resistance temperature detector (RTD), Peltier element, etc., may be employed as a temperature probe for obtaining accurate temperature measurements of component. In at least one implementation, falling temperature-time profile of component under test may be unique to a particular geometry of component under test, its local environment in terms of nearby objects including enclosures and any insulation about component under test, its thermal resistance, and exposure to convection, both natural and forced. In at least one implementation, temperature may be measured by reading temperature probe or set of probes at intervals. For example, a microprocessor may read temperature probe at suitable time intervals and store readings in a memory buffer.

In at least one implementation, at operation 304, a set of recorded temperature data may be subjected to a fitting routine to determine thermal constants k₁ and k₂. In at least one implementation, suitable methods may be employed, such as finite elements for two- and three-dimensional analysis, time increments in a one- and two-dimensional analysis, etc. In at least one implementation, a set of recorded temperatures may be fitted numerically to a heat transfer equation similar to equation [3].

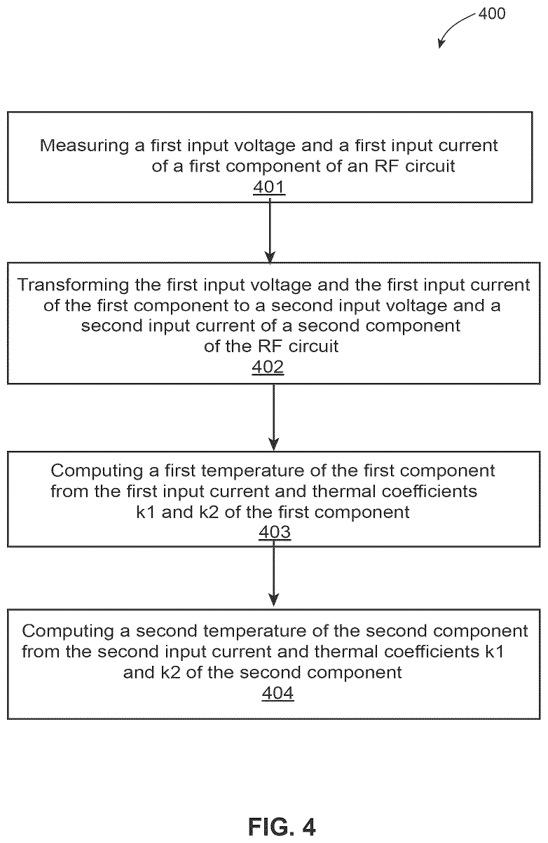

In at least one implementation, by numerically solving heat transfer equation, thermal constants k₁ and k₂ may be computed for component under test. In at least one implementation, method 300 may be repeated for some or all components in an RF power delivery network, similar to RF power delivery network 114 in FIG. 1. In at least one implementation, all components within a particular RF power delivery network may be evaluated by method 300, or selected components that exhibit temperature sensitivity may be thus evaluated. In at least one implementation, once values of k₁ and k₂ are determined for components of interest, they may be applied to temperature computations based on equation [3] as described for FIG. 2 and FIG. 4 below.

FIG. 4 illustrates a method 400 for determining temperatures of multiple components in a power delivery network such as power delivery network 114 shown in FIG. 1, in accordance with at least one implementation. In at least one implementation, operations of method 400 may be performed by software, hardware, or a combination of them. In at least one implementation, method 400 protects temperature-sensitive circuit elements and components from overheating. In at least one implementation, thermal characterization of a components to be employed in a power delivery network may be determined empirically a priori as shown in FIG. 3 and is described above. In at least one implementation, method 400 may parallel description associated with FIG. 2. In at least one implementation, method 400 illustrates operations 401-404 that may be employed to transform currents and voltages measured at a single node in power delivery network to voltages and currents at some or all nodes in power delivery network and compute component temperatures. In at least one implementation, temperature computations may be based on thermal constants k₁ and k₂ of individual components obtained by method 300 previously described.

In at least one implementation, at operation 401, RF voltage and current are measured at a single node in power delivery network by a sensor to measure RF voltages and currents, such as sensor 140 shown in FIG. 1. In at least one implementation, sensor may be an RF current-voltage probe, such as sensor 228 shown in FIG. 2, a vector network analyzer, an impedance analyzer, and like. In at least one implementation, pertinent data may include instantaneous RF voltage, RF current and optionally a phase angle between RF voltage and RF current. In at least one implementation, a vector network analyzer or an impedance analyzer may automatically measure all three parameters. In at least one implementation, phase angle may be necessary to compute complex impedances of input and output ports of components. In at least one implementation, ultimately, current and/or voltage at measurement node is to be transformed to voltages, currents, and optionally complex impedances at some or all of nodes in power delivery network.

In at least one implementation, measurements may be performed sequentially by reading of sensor by a microprocessor at programmed time intervals, such as processor 144 shown in FIG. 1. In at least one implementation, microprocessor may execute software instructions stored on a memory coupled to microprocessor, such as memory 146 shown in FIG. 1. In at least one implementation, instructions may be contained within a software loop, so that measurements may be executed at consistent time intervals. In at least one implementation, read data may be stored in a buffer.

In at least one implementation, at operation 402, sensor coupled to a single node in RF power network may measure input voltage and current of a downstream component coupled to same node. In at least one implementation, measured voltage, current and optionally phase angle may be numerically transformed by processor to voltages and currents at nodes upstream and downstream of measurement node. In at least one implementation, numerical transformations may be performed by subroutines contained within software comprising machine-readable instructions to compute [V, I] vectors for individual nodes (e.g., nodes 208, 210, 214 shown in FIG. 2) by digital manipulation of equation [2]. In at least one implementation, equation [2] incorporates transfer matrices for two-port networks similar to those shown above. In at least one implementation, matrix coefficients, such as A, B, C, and D coefficients described above may be determined empirically or known for individual components of RF power transfer network. In at least one implementation, voltages and currents at upstream and downstream nodes are packaged in calculated [V, I] vectors, and may be equated to input voltages and currents to individual components with which they are associated.

In at least one implementation, at operation 403, computed input currents and/or voltages of a first component (e.g., component N) from transformation of measured data performed at operation 402 may be converted to power dissipation by Joule heating. In at least one implementation, input current i_{Nin} to a component N, may be inserted into a computation involving i²_{Nin}R to obtain Joule heating power loss. In at least one implementation, input voltage V_{Nin} may be employed in a similar manner by computing V²Nin/R. In at least one implementation, parameter R may be total series resistances associated with circuit elements in component.

In at least one implementation, temperature of first component may be determined by insertion of I²R data or simply input current to first component in equation [3]. In at least one implementation, thermal constants k₁ and k₂ may have been determined a priori by prior execution of method 300. Referring again to FIG. 4, by numerically solving equation [3], in at least one implementation, computed time-dependent temperature T (t) may be compared to a maximum temperature limit to determine whether limit has been exceeded. In at least one implementation, maximum temperature limit may be taken from manufacturer of one or more temperature sensitive circuit elements within component. In at least one implementation, if exceeded, software may comprise instructions to remedy overtemperature condition by setting an alarm for user to be aware of overtemperature condition, and to take evasive action to reduce component temperature.

In at least one implementation, evasive action may be reduction of an entire duty cycle period, and/or reduction of on-time phase of duty cycle. Such action may permit component to cool to a certain extent between current bursts, where transient temperature may relax to a temperature below limit. In at least one implementation, manipulation of duty cycle may permit peak power to remain high, as it may be necessary to maintain a desired/target electron density within plasma (such as ne of at least 10¹⁰/cm³).

In at least one implementation, at operation 404, process described for operation 403 may be repeated for a second component (e.g., component N−1) in power delivery network. In at least one implementation, computed time-dependent temperature of second component may be compared to a maximum temperature limit for one or more temperature sensitive circuit elements of second component. In at least one implementation, a similar remedy course for an over-temperature condition in first component may be taken for second component as described for operation 403.

While method 400 may describe measurement, transformation, and temperature computation and overtemperature condition remedy process for two components in power delivery network, it may be repeated to compute temperatures of some or all of remaining components within same power delivery network, in accordance with at least one implementation. As a result, an overtemperature condition that may occur in any one component in power distribution network may be avoided or rapidly remedied.

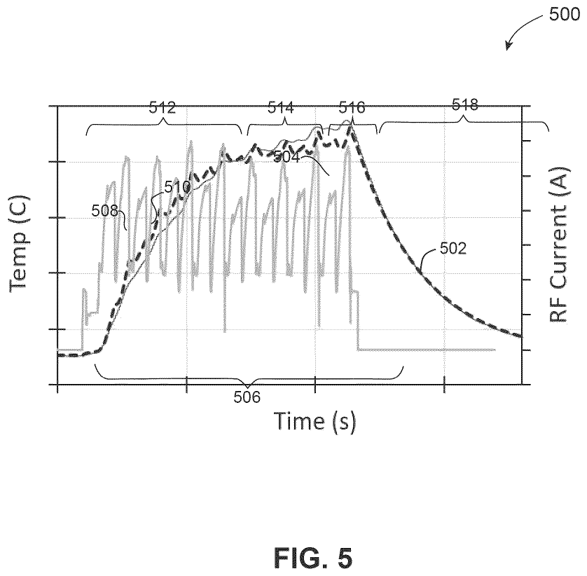

FIG. 5 illustrates plot 500 of measured and calculated temperature vs. time of an exemplary component employed in a power distribution network, such as power delivery network 114, in accordance with at least one implementation. In at least one implementation, exemplary component may be an individual passive circuit element such as a capacitor, inductor, resistor, switch, transmission line, etc. In at least one implementation, component may also be a combination of individual passive elements, such as in an LC filter or impedance matching network. Plot 500 shows a comparison between calculated temperature-time profile (curve 502) and measured temperature-time profile (curve 504) displayed over a time interval, in accordance with at least one implementation. Curve 502 is dashed for ease of discernment from curve 504, which is represented by solid curve. In at least one implementation, calculated temperature-time profile is based on methods described for FIGS. 2, 3 and 4.

Referring again to FIG. 5, an exemplary plot 500 shows that calculated temperature-time profile substantially tracks measured temperature-time profile by application of method as described above, in accordance with at least one implementation. In at least one implementation, RF current levels are also shown in plot 500 as a train of current bursts or pulses that are shown as pulse train 506. In at least one implementation, current pulse durations may be based on on-time phases spaced apart by even duty cycle periods. In at least one implementation, pulse duration may be governed by a substantially constant duty cycle. In exemplary plot 500, current pulses comprise large magnitude current pulses 508 followed by lower-magnitude current pulses 510, in accordance with at least one implementation. Plot 500 shows an initial rapid temperature rise in region 512, where RF current is continuous. Region 514 follows region 512. In region 514, on and off durations of current pulse train 506 remains same as in region 512. In at least one implementation, current peaks have lower magnitudes, permitting a plateau to develop in both measured and calculated temperature-time profiles. In at least one implementation, duration of bursts (e.g., width of current pulses 508 and 510) may be 10-20 seconds, for example, corresponding to an on-time phase of duty cycle. In at least one implementation, in region 516, magnitude of current pulses 508 and 510 increases substantially to levels in region 512, In at least one implementation, both measured and calculated temperature-time profile curves respond by rising. In at least one implementation, in region 518, current pulse train is stopped, and temperature decreases monotonically. Calculated curve 504 accurately follows measured curve 502.

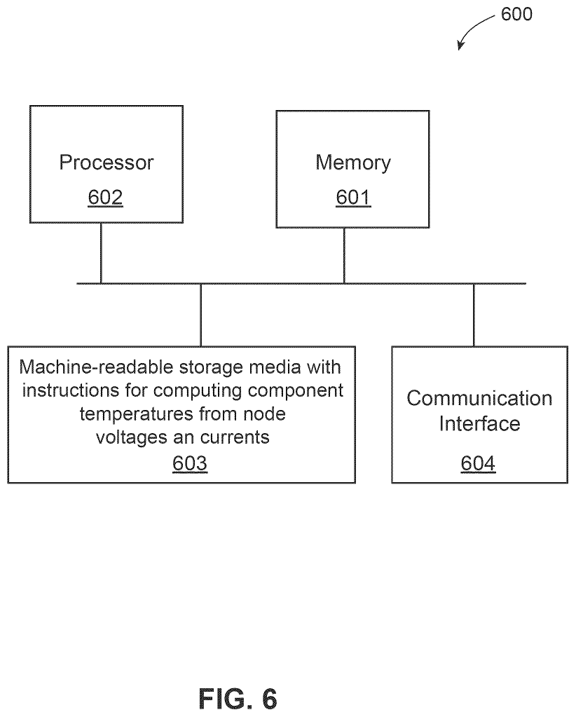

FIG. 6 illustrates processor system 600 with a machine-readable storage medium having machine-readable instructions that when executed cause a microcontroller (e.g., processor 144 in FIG. 1 or processor 230 in FIG. 2) in a circuit board of a control unit for plasma process tool 100 to execute machine-readable instructions according to method 400, for example. In at least one implementation, microcontroller may measure and report voltages and/or currents at nodes within RF power delivery network 114 coupling RF signal sources 126 and 128 with plasma chamber 102. In at least one implementation, processes may be stored in a machine-readable medium (e.g., 603) as computer-executable instructions. In at least one implementation, a machine-readable storage medium may be memory 146 in FIG. 1 or memory 232 in FIG. 2, for example. In at least one implementation, processor system 600 comprises memory 601, processor 602, machine-readable storage media 603 (also referred to as tangible machine-readable medium), communication interface 604 (e.g., wireless or wired interface), and network bus 605 coupled together as shown. In at least one implementation, processor 602 may represent processor 144 in FIG. 1.

In at least one implementation, processor 602 is a Digital Signal Processor (DSP), an Application Specific Integrated Circuit (ASIC), a general-purpose Central Processing Unit (CPU), or a low power logic implementing a simple finite state machine to perform various processes described herein.

In at least one implementation, various logic blocks of processor system 600 are coupled together via network bus 605. Any suitable protocol may be used to implement network bus 605. In at least one implementation, machine-readable storage medium 603 includes instructions (also referred to as program software code/instructions) for measuring voltages and currents, transforming measured voltages and currents and computing temperatures, as described above with reference to various implementations.

In at least one implementation, machine-readable storage media 603 is a machine-readable storage media with instructions for measuring currents and voltages at nodes between components in an RF power delivery network (e.g., RF power delivery network 114 in FIG. 1). In at least one implementation, machine-readable medium 603 (e.g., memory 146 in FIG. 1) has machine-readable instructions, that when executed, cause processor 602 to perform method with reference to various implementations.

In at least one implementation, program software code/instructions associated with various implementations may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In at least one implementation, program software code/instructions are executed by processor system 600.

In at least one implementation, machine-readable storage media 603 is a computer executable storage medium. In at least one implementation, program software code/instructions associated with various implementations are stored in computer executable storage medium 603 and executed by processor 602. Here, computer executable storage medium 603 is a tangible machine-readable medium 603 that can be used to store program software code/instructions and data that, when executed by a computing device, causes one or more processors (e.g., processor 602) to perform a process.

In at least one implementation, tangible machine-readable medium 603 may include storage of executable software program code/instructions and data in various tangible locations, including for example, ROM, volatile RAM, non-volatile memory and/or cache and/or other tangible memory as referenced in present application. In at least one implementation, portions of this program software code/instructions and/or data may be stored in any one of these storage and memory devices. In at least one implementation, program software code/instructions can be obtained from other storage, including, e.g., through centralized servers or peer to peer networks and like, including Internet. In at least one implementation, different portions of software program code/instructions and data can be obtained at different times and in different communication sessions or in same communication session.

In at least one implementation, software program code/instructions associated with various implementations can be obtained in their entirety prior to execution of a respective software program or application. In at least one implementation, alternatively, portions of software program code/instructions and data can be obtained dynamically, e.g., just in time, when needed for execution. In at least one implementation, alternatively, some combination of these ways of obtaining software program code/instructions and data may occur, e.g., for different applications, components, programs, objects, modules, routines or other sequences of instructions or organization of sequences of instructions, by way of example. In at least one implementation, it may not be required that data and instructions be on a tangible machine-readable medium 603 in entirety at a particular instance of time.

In at least one implementation, tangible machine-readable medium 603 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMs), Digital Versatile Disks (DVDs), etc.), among others. In at least one implementation, software program code/instructions may be temporarily stored in digital tangible communication links while implementing electrical, optical, acoustical, or other forms of propagating signals, such as carrier waves, infrared signals, digital signals, etc. through such tangible communication links.

Following examples are provided that illustrate various implementations. Examples can be combined with other examples. As such, various implementations can be combined with other implementations without changing the scope of the invention.

Example 1 is a method for measuring temperature, comprising: providing a radio frequency (RF) current to a RF power delivery network, wherein the RF power delivery network comprises at least a first component coupled to a second component, wherein the first component comprises a first node, the second component comprises a second node, wherein the second node interconnects the first component and the second component; measuring a first voltage and a first current at the first node; based on the measuring of the first voltage and the measuring of the first current, computing a second voltage and a second current at the second node, and computing a first temperature of the first component and a second temperature of the second component, wherein the first temperature is a function of the first current and the second temperature is a function of the second current.

Example 2 is the method of any example herein, particularly example 1, wherein computing the second voltage and the second current comprises transforming the first voltage to the second voltage and the first current to the second current based on a first transfer matrix.

Example 3 is the method of any example herein, particularly example 2, further comprising determining a third voltage and a third current, wherein the second voltage is transformed to the third voltage and the second current is transformed to the third current based on a second transfer matrix.

Example 4 is the method of any example herein, particularly example 2, further comprising converting the first current to a first dissipated power of the first component and converting the second current to a second dissipated power of the second component.

Example 5 is the method of any example herein, particularly example 4, wherein computing the first temperature of the first component comprises computing a first integral of the first dissipated power over a time interval.

Example 6 is the method of any example herein, particularly example 5, wherein computing the second temperature of the second component comprises computing a second integral of the second dissipated power over the time interval and multiplying the second integral by a second thermal constant of the second component.

Example 7 is the method of any example herein, particularly example 6, further comprising comparing the first temperature to a first temperature limit of the first component and the second temperature to a second temperature limit of the second component.

Example 8 is the method of any example herein, particularly example 7, further comprising adjusting a duty cycle of the RF current coupled to the RF power delivery network when at least the first temperature exceeds the first temperature limit or at least the second temperature exceeds the second temperature limit.

Example 9 is the method of any example herein, particularly example 2, wherein measuring the first voltage and the first current comprises measuring a phase angle between the first current and the first voltage.

Example 10 is the method of any example herein, particularly example 9, wherein a first output impedance of the first component is determined from the first voltage, the first current and the phase angle between the first current and the first voltage.

Example 11 is a machine-readable storage medium, comprising a computer program for thermally protecting an electronic circuit, wherein the electronic circuit comprises at least a first component and a second component, wherein the computer program comprises machine-executable instructions, that when executed by one or more machines, cause the one or more machines to perform a method comprising measuring a first input voltage and a first input current of the first component; computing a second input voltage and a second input current of the second component; and computing a first temperature of the first component and a second temperature of the second component, wherein the first temperature is a function of the first input current and the second temperature is a function of the second input current.

Example 12 is the machine-readable storage medium of any example herein, particularly example 11, wherein the method further comprises comparing the first temperature to a first temperature limit and comparing the second temperature to a second temperature limit.

Example 13 s the machine-readable storage medium of any example herein, particularly example 12, wherein the method further comprises adjusting a duty cycle of an RF current when at least the first temperature exceeds the first temperature limit, or the second temperature exceeds the second temperature limit.

Example 14 is a system comprising a plasma chamber comprising a plasma coupling interface; a radio frequency (RF) signal source coupled to the plasma coupling interface through a RF power delivery network, wherein the RF power delivery network comprises a plurality of components; a sensor coupled to a first component of the plurality of components, the sensor to measure a first voltage across the first component and a first current through the first component; and a processor coupled to the sensor and to determine a second voltage across a second component of the plurality of components and a second current through the second component and to determine a first temperature in the first component and a second temperature in the second component.

Example 15 is the system of any example herein, particularly example 14, wherein the processor is to determine the second voltage and the second current based on the first voltage and the first current.

Example 16 is the system of any example herein, particularly example 15, wherein the processor is to determine the second voltage and the second current based on a transfer matrix.

Example 17 is the system of any example herein, particularly example 14, wherein the plasma coupling interface comprises an inductively coupled plasma (ICP) antenna, wherein the ICP antenna is to inductively couple to a plasma within the plasma chamber.

Example 18 is the system of any example herein, particularly example 14, wherein the plasma coupling interface is a capacitively coupled plasma (CCP) electrode, wherein the CCP electrode is to capacitively couple to a plasma within the plasma chamber.

Example 19 is the system of any example herein, particularly example 18, wherein the CCP electrode is a gas distribution manifold, and wherein the gas distribution manifold is to capacitively couple to the plasma within the plasma chamber.

Besides what is described herein, various modifications may be made to the disclosed implementations without departing from their scope. Therefore, illustrations of implementations herein should be construed as examples only, and not restrictive to the scope of the present disclosure. The scope of the invention should be measured solely by reference to the claims that follow.

1. A method for measuring temperature, comprising:
applying a radio frequency (RF) current to a RF power delivery network, wherein the RF power delivery network comprises at least a first component coupled to a second component, wherein:
the first component comprises a first node;
the second component comprises a second node; and
the second node interconnects the first component and the second component, wherein the method further comprises:
measuring a first voltage and a first current at the first node;
based on the measuring of the first voltage and the measuring of the first current, computing a second voltage and a second current at the second node, and
computing a first temperature of the first component and a second temperature of the second component, wherein the first temperature is a function of the first current and the second temperature is a function of the second current.

2. The method of claim 1, wherein computing the second voltage and the second current comprises transforming the first voltage to the second voltage and the first current to the second current based on a first transfer matrix.

3. The method of claim 2, further comprising determining a third voltage and a third current, wherein the second voltage is transformed to the third voltage and the second current is transformed to the third current based on a second transfer matrix.

4. The method of claim 2, further comprising:
converting the first current to a first dissipated power of the first component; and
converting the second current to a second dissipated power of the second component.

5. The method of claim 4, wherein computing the first temperature of the first component comprises computing a first integral of the first dissipated power over a time interval.

6. The method of claim 5, wherein computing the second temperature of the second component comprises:
computing a second integral of the second dissipated power over the time interval; and
multiplying the second integral by a second thermal constant of the second component.

7. The method of claim 6, further comprising comparing the first temperature to a first temperature limit of the first component and the second temperature to a second temperature limit of the second component.

8. The method of claim 7, further comprising adjusting a duty cycle of the RF current coupled to the RF power delivery network when at least the first temperature exceeds the first temperature limit or at least the second temperature exceeds the second temperature limit.

9. The method of claim 2, wherein measuring the first voltage and the first current comprises measuring a phase angle between the first current and the first voltage.

10. The method of claim 9, wherein a first output impedance of the first component is determined from the first voltage, the first current, and the phase angle between the first current and the first voltage.

11. A machine-readable storage medium, comprising:
a computer program for thermally protecting an electronic circuit, wherein the electronic circuit comprises at least a first component and a second component, wherein the computer program comprises machine-executable instructions, that when executed by one or more machines, cause the one or more machines to perform a method comprising:
measuring a first input voltage and a first input current of the first component;
computing a second input voltage and a second input current of the second component; and
computing a first temperature of the first component and a second temperature of the second component, wherein the first temperature is a function of the first input current and the second temperature is a function of the second input current.

12. The machine-readable storage medium of claim 11, wherein the method further comprises comparing the first temperature to a first temperature limit and comparing the second temperature to a second temperature limit.

13. The machine-readable storage medium of claim 12, wherein the method further comprises adjusting a duty cycle of an RF current when at least the first temperature exceeds the first temperature limit, or the second temperature exceeds the second temperature limit.

14. A system comprising:
a plasma chamber comprising a plasma coupling interface;
a radio frequency (RF) signal source coupled to the plasma coupling interface through a RF power delivery network, wherein the RF power delivery network comprises a plurality of components;
a sensor coupled to a first component of the plurality of components, the sensor to measure a first voltage across the first component and a first current through the first component; and
a processor coupled to the sensor and to determine a second voltage across a second component of the plurality of components and a second current through the second component and to determine a first temperature in the first component and a second temperature in the second component.

15. The system of claim 14, wherein the processor is to determine the second voltage and the second current based on the first voltage and the first current.

16. The system of claim 15, wherein the processor is to determine the second voltage and the second current based on a transfer matrix.

17. The system of claim 14, wherein the plasma coupling interface comprises an inductively coupled plasma (ICP) antenna, and wherein the ICP antenna is to inductively couple to a plasma within the plasma chamber.

18. The system of claim 14, wherein the plasma coupling interface is a capacitively coupled plasma (CCP) electrode, and wherein the CCP electrode is to capacitively couple to a plasma within the plasma chamber.

19. The system of claim 18, wherein the CCP electrode is a gas distribution manifold, and wherein the gas distribution manifold is to capacitively couple to the plasma within the plasma chamber.
